(19) United States
(12) Patent Application Publication
(10) Pub. No.: US 2005/0100177 A1
(43) Pub. Date: May 12, 2005

(54) MUTE CIRCUIT OF AN AUDIO DEVICE FOR SUPPRESSING AUDIO SIGNALS DURING TRANSIENTS OF POWER SWITCHING

(76) Inventor: ING-MING LEE, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/904,343

(22) Filed: Nov. 4, 2004

(30) Foreign Application Priority Data
Nov. 6, 2003 (TW) 092131146

(51) Int. Cl. H04B 15/00; H03F 1/14

(52) U.S. Cl. 381/94.5; 330/51

(57) ABSTRACT

The present invention discloses a mute circuit of an audio device for suppressing audio signals during the transients of power switching. A mute circuit for an amplifier having at least an audio output terminal includes at least one bypass device, each of which has a controlling terminal and is capable of providing a path from the audio output terminal to a ground when the controlling terminal is turned on; a power-on controlling circuit for turning on the controlling terminal of the bypass device during a first period of time after a power-on transient; a fixed-voltage supply for stopping the amplifier during the power-on transient according to a control of a controlling terminal of an input/output port; and a power-off controlling circuit for turning on the controlling terminal of the bypass device by utilizing a voltage of a capacitor during a second period of time after a power-off transient.

### BACKGROUND OF THE INVENTION

1. Field of the Invention

The present invention relates to a controlling circuit for an audio signal, and more particularly, to a mute circuit for suppressing audio signals during power switching.

2. Description of the Prior Art

FIG. 1 is a diagram of a prior art audio signal circuit in an audio device. An audio device 10 (such as a player) contains a core processor, the microprocessor 12, for receiving many types of audio-video data 20, and for transmitting the audio data 22, portion of the audio-video data 20, to the audio chip 14 and the video data portion of the audio-video data 20 to the video chip (not shown).

The audio chip 14 divides the audio data 22 into at least a left channel signal L′ and a right channel signal R′, and sometimes into more channel signals. These signals are sent to the pre-amplifier 16 to be amplified, which then further sends these signals outside the device 10 to the post-amplifier and the speakers (not shown).

A problem in the available players and stereos has not been solved completely for a long time—a transient noise occurs during power switching. During the transient when the power switches on or off, there are inevitable noises attached to the audio signals since the power supply is not in a steady state. When these audio signals are amplified and sent out by the speakers, there will be annoying sounds.

Although there are chips for suppressing the noises, which occur during power switching to solve the above-mentioned problem, using these kinds of chips increases the costs of the players, and these kinds of chips do not erase the noises completely, instead merely suppressing the noises.

### SUMMARY OF THE INVENTION

It is therefore one of the objectives of the present invention to provide a mute circuit for audio devices. During the transient of switching on or off, the audio signals are bypassed to the ground to avoid transmitting them to the post-amplifier.

According to one preferred embodiment of the present invention, a mute circuit for an amplifier having at least an audio output terminal is disclosed. The mute circuit includes: at least one bypass device, each of which has a controlling terminal, such that when the controlling terminal is turned on, the bypass device provides a path from the audio output terminal to a ground; a power-on controlling circuit for turning on the controlling terminal of the bypass device during a first period of time after a power-on transient; a fixed-voltage supply for stopping the amplifier during the power-on transient according to a control of a controlling terminal of an input/output port; and a power-off controlling circuit for turning on the controlling terminal of the bypass device during a second period of time by using a voltage of a capacitor after a power-off transient.

It is one advantage of the present invention that a mute circuit is provided to eliminate noise occurring during a power-on or power-off transient. As a result, there will be no spurious noises sent out by the speakers when the audio device is turned on or off.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a prior art audio signal circuit in an audio device.

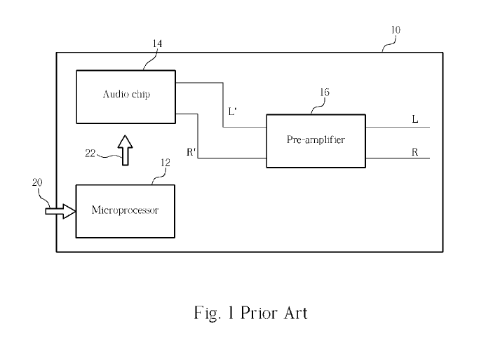

FIG. 2 is a mute circuit according to the present invention.

FIG. 3 is a diagram of a voltage stabilizer shown in FIG. 2.

FIG. 4 is a diagram of a charge/discharge circuit shown in FIG. 2.

### DETAILED DESCRIPTION

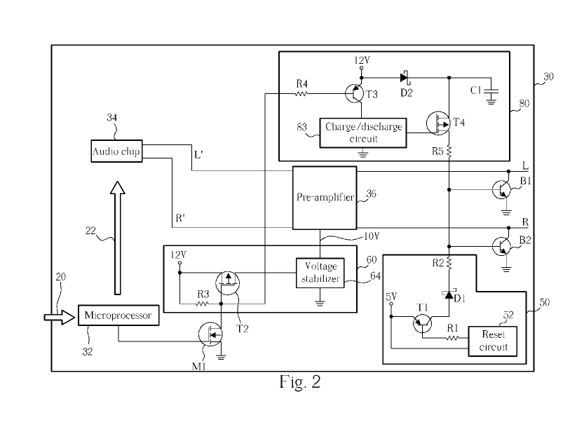

FIG. 2 shows a mute circuit for an audio device of the present invention. An audio device 30 contains a core processor, the microprocessor 32, which receives audio-video data 20 of many specifications, and transmits the audio data 22, portion of the audio-video data 20, to an audio chip 34 and the video data portion of the audio video data 20 to a video chip (not shown).

The audio chip 34 divides the audio data 22 into at least the left channel signal L′ and the right channel signal R′, and sometimes into more channel signals. These signals are sent to the pre-amplifier 36 to be amplified, which subsequently sends them to the post-amplifier and the speakers (not shown).

According to one preferred embodiment of the present invention, two bypass transistors B1 and B2 are respectively coupled to the left channel output and right channel output of the pre-amplifier 36. The two bypass transistors B1 and B2 are NPN bipolar junction transistors on which the collectors are coupled to the outputs of the pre-amplifier 36, the emitters are coupled to the ground, and the bases are used to switch the states of the bypass transistors B1 and B2 between on and off.

A power-on controlling circuit 50 is used to switch the bypass transistors B1 and B2 to an on state and then an off state when the power switches on. The power-on controlling circuit 50 contains a reset circuit 52 and a first switch transistor T1 used as a switch. The reset circuit 52 is connected to a 5-volt power supply voltage to monitor the changes of the 5-volt power supply voltage when the audio device is turned on. The reset circuit 52 sends out a low level signal when the output of the 5-volt power supply voltage is lower than 4.38 volts, and sends out a high level signal when the output of the 5-volt power supply voltage is higher than 4.38 volts. The first switch transistor T1 is a PNP bipolar junction transistor on which the emitter is coupled to the power supply, the base is coupled to the output of the reset circuit 52 through a first resistor R1, and the collector is coupled to the positive terminal of a Schottky diode D1. The negative terminal of the Schottky diode D1 is coupled to the bases of the bypass transistors B1 and B2 through a second resistor R2.

A fixed-voltage supply 60 is used for powering the pre-amplifier 36. The fixed-voltage supply 60 receives a 12-volt power supply voltage and transmits it to a voltage stabilizer 64 through a second switch transistor T2. The voltage stabilizer 64 receives a 12-volt power supply voltage and then outputs a voltage of 10 volts to power the pre-amplifier 36. The second switch transistor T2 is a PMOS transistor on which the source is coupled to the 12-volt power supply voltage, the gate is coupled to the 12-volt power supply voltage through a third resistor R3, and the drain is coupled to the voltage stabilizer 64.

The on and off of the second switch transistor T2 are controlled by a controlling terminal of an I/O (input-output) port of the microprocessor 32. The controlling terminal of an I/O port can be any I/O port of the microprocessor 32, which is normally at a low level. The controlling terminal of the I/O port is coupled to the gate of a pull down transistor M1, which is an NMOS transistor on which the drain is coupled to the gate of the second switch transistor T2 and the source is coupled to the ground.

A power-off controlling circuit 80 contains a fourth resistor R4 connected between the drain of the pull down transistor M1 and the base of a third switch transistor T3. The third switch transistor T3 is a PNP bipolar transistor, on which the emitter is coupled to the 12-volt power supply voltage, and the collector is coupled to a charge/discharge circuit 83. The charge/discharge circuit 83 outputs a high voltage when the third switch transistor T3 switches on, and outputs a low voltage when the third switch transistor T3 switches off. In addition, there is a second Schottky diode D2 on which the positive terminal is coupled to the 12-volt power supply voltage, and the negative terminal is coupled to the ground through a first capacitor C1. The fourth switch transistor T4 is a PMOS transistor on which the gate is coupled to the output of the charge/discharge circuit 83, the source is coupled to the negative terminal of the first Schottky diode D1, and the drain is coupled to the bases of the bypass transistors B1 and B2 through a fifth resistor R5.

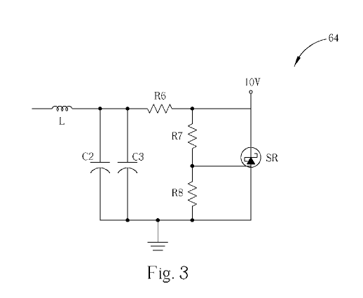

FIG. 3 is a diagram of the voltage stabilizer 64 shown in FIG. 2. The voltage stabilizer 64 contains an inductor L, one terminal of which is coupled to the drain of the second switch transistor T2; the second capacitor C2 and the third capacitor C3, which are connected in parallel, couple the other terminal of the inductor L to the ground. The sixth, seventh, and eighth resistors R6, R7 and R8, which are connected in serial, are connected in parallel with the third capacitor C3. The positive terminal of the shunt regulator SR is coupled to the ground, the negative terminal is coupled to the node between the sixth and the seventh resistors R6 and R7, and the reference terminal is coupled to the node between the seventh and the eighth transistors R7 and R8. As a result, when the second switch transistor T2 switches on, by the action of the shunt regulator SR and the voltage division of the sixth, seventh and eighth resistors R6, R7 and R8, the node between the sixth and the seventh resistors R6 and R7 provides a steady voltage of 10 volts.

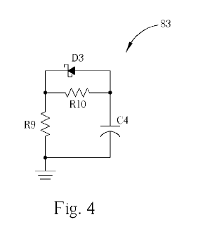

FIG. 4 is a diagram of the charge/discharge circuit 83 shown in FIG. 2. A ninth resistor R9 is connected between the collector of the third switch transistor T3 and the ground. The series of the tenth resistor R10 and the fourth capacitor C4 is connected in parallel with the ninth resistor R9. The negative terminal of the third Schottky diode D3 is coupled to the node between the ninth and the tenth resistors R9 and R10, and the positive terminal, which is also the output terminal of the charge/discharge circuit 83, is coupled to the node between the tenth resistor R10 and the fourth capacitor C4. When the third switch transistor T3 switches on, the tenth resistor R10 along with the fourth capacitor C4 form an RC charging circuit, and the fourth capacitor C4 receives a 12-volt power supply voltage when the RC charging circuit is in the steady state. At this time, the output terminal of the charge/discharge circuit 83 is high. Similarly, when the third switch transistor T3 switches off, the charge on the fourth capacitor C4 is dissipated rapidly through the third Schottky diode D3 and the ninth resistor R9. At this time, the output terminal of the charge/discharge circuit 83 is low.

According to the present invention, the mute circuit behaves as follows when the power switches on, during normal operation, and when the power switches off.

### EXAMPLE 1

### During the Transient when the Audio Device is Powered on

Because the controlling terminal of the I/O port is normally low, the pull down transistor M1 turns off and hence the gate of the second switch transistor T2 is connected to the 12-volt power supply voltage. As a result, the second switch transistor T2 also turns off so that the voltage stabilizer 64 cannot be powered by 12-volt power supply voltage, and therefore, the pre-amplifier 36 receives no power. Consequently, the pre-amplifier 36 will output no sound during the transient when the power switches on.

It is also important to avoid the situation where the pre-amplifier 36 still outputs noise after the audio device is powered on. When the 5-volt power supply voltage changes from 0 to 4.38 volts (the first period of time), because the 5-volt power supply voltage in the power-on controlling circuit 50 is not stable during the transient when the audio device is powered on, the reset circuit 52 sends a low level signal to the first switch transistor T1 to turn on the first switch transistor T1. That is, the controlling terminals of the bypass transistors B1 and B2 receive an increasing voltage, so the bypass transistors B1 and B2 turn on, conducting all signals from the audio output terminal of the pre-amplifier 36 to the ground. As a result, during the transient when the audio device is powered on, by not powering the pre-amplifier 36 and conducting all signals from the audio output terminal of the pre-amplifier 36 to the ground, all signals are blocked from being sent to the post-amplifier (not shown).

When the output of the 5-volt power supply voltage exceeds 4.38 volts, the reset circuit 52 sends a high level signal to the first switch transistor T1 to turn off the first switch transistor T1 so that the bypass transistors B1 and B2 turn off as well. As a result, all signals from the audio output terminal of the pre-amplifier 36 are sent to the post-amplifier (not shown).

### EXAMPLE 2

### When the Audio Device 30 is Running

The controlling terminal of the I/O port sends a high level signal to turn on the pull down transistor M1—coupling the gate of the second switch transistor T2 to the ground. As a result, the second switch transistor T2 also turns on so that the 12-volt power supply voltage will power the voltage stabilizer 64, and consequently the pre-amplifier 36 will operate.

Moreover, because the pull down transistor M1 is turned on, the third switch transistor T3 is also turned on. As a result, the charge/discharge circuit 83 sends out a high level signal to turn off the fourth switch transistor T4. As a result, when the audio device is running, the bypass transistors B1 and B2 are off, and the first capacitor C1 is charged to 12 volts through the second Schottky diode D2.

### EXAMPLE 3

### During the Transient When the Audio Device is Powered Off

The third switch transistor T3 is turned off, the charge/discharge circuit 83 sends out a low level signal to turn on the fourth switch transistor T4, and the bypass transistors B1 and B2 are turned on by the voltage of the first capacitor C1. Before the charge of the first capacitor C1 vanishes (the second period of time), i.e., when the bypass transistors B1 and B2 are still on, all signals from the audio output terminal of the pre-amplifier 36 are coupled to the ground. As a result, during the transient when the audio device is powered off, all signals on the audio output terminal of the pre-amplifier 36 are blocked from being sent to the post-amplifier (not shown).

In summary, in the present invention, the power-on controlling circuit 50 turns on the bypass transistors B1 and B2 during the transient when the audio device is powered on, so the audio signals are coupled to the ground through the bypass path. This prevents the spurious noises generated by the pre-amplifier 36 from being sent to the post-amplifier. Moreover, right after the audio device 30 is powered on, the fixed-voltage supply 60 uses the controlling terminal of the I/O port to stop powering the pre-amplifier 36 in order to eliminate the noises. Finally, during the transient when the audio device is powered off, the power-off controlling circuit 80 turns on the bypass transistors B1 and B2 when the fourth switch transistor T4 is turned on, using the voltage of the first capacitor C1. This prevents the spurious noises generated by the pre-amplifier 36 from being sent to the post-amplifier.

In conclusion, the present invention provides a mute circuit for coupling the signals from the audio output terminals of the pre-amplifier to the ground to prevent them from being sent to the post-amplifier during the transients when an audio device is powered on or off.

Those skilled in the art will readily observe that numerous modifications and alterations of the device and method may be made while retaining the teachings of the invention. Accordingly, the above disclosure should be construed as limited only by the metes and bounds of the appended claims.

1. A mute circuit for an amplifier having at least an audio output terminal, comprising:
at least one bypass device, each of which has a controlling terminal, the bypass device provides a path from the audio output terminal to a ground when the controlling terminal is turned on;
a power-on controlling circuit for turning on the controlling terminal of the bypass device during a first period of time after a power-on transient;
a fixed-voltage supply for stopping the amplifier from operating during the power-on transient according to a control of a controlling terminal of an input/output port; and
a power-off controlling circuit comprising a capacitor, the power-off controlling circuit for turning on the controlling terminal of the bypass device by utilizing a voltage provided by the capacitor during a second period of time after a power-off transient.

2. The mute circuit of claim 1, wherein the bypass device is a bipolar junction transistor.

3. The mute circuit of claim 2, wherein the bipolar junction transistor is an NPN bipolar junction transistor having a collector coupled to the audio output terminal, an emitter coupled to the ground, and a base being the controlling terminal.

4. The mute circuit of claim 1, wherein the power-on controlling circuit comprises:
a reset circuit for sending a signal during the first period of time immediately after the power-on transient; and
a switching device for turning on the controlling terminal of the bypass device according to the signal.

5. The mute circuit of claim 1, wherein the fixed-voltage supplier comprises:
a switching device for providing a power supply voltage according to the control of the controlling terminal of the input/output port; and
a voltage stabilizer for transforming the power supply voltage into a specific voltage and providing the amplifier with the specific voltage.

6. The mute circuit of claim 5, wherein the controlling terminal of the input/output port has a normal signal after the power-on transient to prevent the switching device from providing the power supply voltage to the voltage stabilizer.

7. The mute circuit of claim 1, wherein the power-off controlling circuit further comprises:
a first switching device for providing a power supply voltage according to the control of the controlling terminal of the input/output port;
a controller for generating a turn-on signal when the controller does not receive the power supply voltage from the first switching device;
a Schottky diode having a positive terminal coupled to the power supply voltage; and
a second switching device for using the voltage on the capacitor to turn on the controlling terminal of the bypass device when the second switching device receives the turn-on signal;
wherein the capacitor is electrically connected between a negative terminal of the Schottky diode and the ground.

8. A mute circuit for an amplifier having at least an audio output terminal, comprising:
at least one bypass device, each of which has a controlling terminal, the bypass device providing a path from the audio output terminal to a ground when the controlling terminal is turned on;
a power-on controlling circuit for turning on the controlling terminal of the bypass device during a first period of time after a power-on transient; and
a power-off controlling circuit comprising a capacitor, the power-off controlling circuit for turning on the controlling terminal of the bypass device by utilizing a voltage provided by the capacitor during a second period of time after a power-off transient.

9. The mute circuit of claim 8, wherein the bypass device is a bipolar junction transistor.

10. The mute circuit of claim 9, wherein the bipolar junction transistor is an NPN bipolar junction transistor having a collector coupled to the audio output terminal, an emitter coupled to the ground, and a base being the controlling terminal.

11. The mute circuit of claim 8, wherein the power-on controlling circuit comprises:
a reset circuit for sending a signal during the first period of time immediately after the power-on transient; and
a switching device for turning on the terminal of the bypass device according to the signal.

12. The mute circuit of claim 8, wherein the power-off controlling circuit further comprises:
a first switching device for providing a power supply voltage according to the control of the controlling terminal of the input/output port;
a controller for generating a turn-on signal when the controller does not receive the power supply voltage from the first switching device;
a Schottky diode having a positive terminal coupled to the power supply voltage; and
a second switching device for using the voltage on the capacitor to turn on the controlling terminal of the bypass device when the second switching device receives the turn-on signal;
wherein the capacitor is electrically connected between a negative terminal of the Schottky diode and the ground.

13. A mute circuit for an amplifier having at least one audio output terminal, comprising:
at least one bypass device, each of which has a controlling terminal, the bypass device providing a path from the audio output terminal to a ground when the controlling terminal is turned on; and
a power-on controlling circuit for turning on the controlling terminal of the bypass device during a period of time after a power-on transient.

14. The mute circuit of claim 13, wherein the bypass device is a bipolar junction transistor.

15. The mute circuit of claim 14, wherein the bipolar junction transistor is an NPN bipolar junction transistor having a collector coupled to the audio output terminal, an emitter coupled to the ground, and a base being the controlling terminal.

16. The mute circuit of claim 13, wherein the power-on controlling circuit comprises:
a reset circuit for sending a signal during the period of time immediately after the power-on transient; and
a switching device for turning on the terminal of the bypass device according to the signal.

17. A mute circuit for an amplifier having at least one audio output terminal, comprising:
at least one bypass device, each of which has a controlling terminal, the bypass device providing a path from the audio output terminal to a ground when the controlling terminal is turned on; and
a power-off controlling circuit comprising a capacitor, the power-off controlling circuit for turning on the controlling terminal of the bypass device by utilizing a voltage provided by the capacitor during a period of time after a power-off transient.

18. The mute circuit of claim 17, wherein the bypass device is a bipolar junction transistor.

19. The mute circuit of claim 18, wherein the bipolar junction transistor is an NPN bipolar junction transistor having a collector coupled to the audio output terminal, an emitter coupled to the ground, and a base being the controlling terminal.

20. The mute circuit of claim 17, wherein the power-off controlling circuit further comprises:
a first switching device for providing a power supply voltage according to the control of the controlling terminal of the input/output port;
a controller for generating a turn-on signal when the controller does not receive the power supply voltage from the first switching device;
a Schottky diode having a positive terminal coupled to the power supply voltage; and
a second switching device for using the voltage on the capacitor to turn on the controlling terminal of the bypass device when the second switching device receives the turn-on signal;
wherein the capacitor is electrically connected between a negative terminal of the Schottky diode and the ground.
